(19) United States
(12) Patent Application Publication
(10) Pub. No.: US 2016/0322598 A1
(43) Pub. Date: Nov. 3, 2016

(54) ORGANIC LIGHT-EMITTING DISPLAY APPARATUS AND METHOD OF MANUFACTURING THE SAME

(71) Applicant: SAMSUNG DISPLAY CO., LTD., Yongin-si (KR)

(72) Inventors: Yongtack Kim, Yongin-si (KR); Eungseok Park, Yongin-si (KR); Wonmin Yun, Yongin-si (KR); Byoungduk Lee, Yongin-si (KR); Yunah Chung, Yongin-si (KR); Yoonhyeung Cho, Yongin-si (KR); Yongchan Ju, Yongin-si (KR)

(21) Appl. No.: 14/936,591

(22) Filed: Nov. 9, 2015

(30) Foreign Application Priority Data
Apr. 29, 2015 (KR) 10-2015-0060725

(51) Int. Cl. H01L 51/52; H01L 51/56; H01L 27/32

(52) U.S. Cl. CPC H01L 51/5253; H01L 27/3244; H01L 51/56; H01L 2251/303; H01L 2251/558

(57) ABSTRACT

An organic light-emitting display apparatus includes: a substrate; an organic light-emitting device on the substrate; and an encapsulation layer including a first inorganic film covering the organic light-emitting device, an organic film on the first inorganic film, a second inorganic film between the first inorganic film and the organic film and having hydrophilicity, and a third inorganic film on the organic film. The second inorganic film may have a contact angle of 40° or less. A method of manufacturing an organic light-emitting display apparatus includes forming an organic light-emitting device on a substrate; forming a first inorganic film covering the organic light-emitting device; forming a second inorganic film having hydrophilicity on the first inorganic film; forming an organic film on the second inorganic film; and forming a third inorganic film on the organic film.

### CROSS-REFERENCE TO RELATED APPLICATIONS

This application claims priority to and the benefit of Korean Patent Application No. 10-2015-0030547, filed on March 4, 2015 in the Korean Intellectual Property Office, and Korean Patent Application No. 10-2015-0060725, filed on Apr. 29, 2015 in the Korean Intellectual Property Office, the entire contents of all of which are incorporated herein by reference.

### BACKGROUND

1. Field

Aspects of embodiments of the present invention relate to an organic light-emitting display apparatus and a method of manufacturing the organic light-emitting display apparatus.

2. Description of the Related Art

Among display apparatuses, organic light-emitting display apparatuses are attracting much attention as next-generation display apparatuses due to their features such as wide viewing angles, excellent contrast ratios, and fast response rates. In general, an organic light-emitting display apparatus has thin film transistors (TFTs) and organic light-emitting devices formed on a substrate, and the organic light-emitting devices emit light by themselves. The organic light-emitting display apparatus is used not only as a display for a compact product such as a cell phone but also as a display for a large product such as a television.

Organic light-emitting devices of an organic light-emitting display apparatus are vulnerable to oxygen and moisture. Accordingly, a structure capable of sealing the organic light-emitting devices may be formed on the organic light-emitting devices to protect the organic light-emitting devices from external oxygen and moisture.

However, comparable organic light-emitting display apparatuses and methods of manufacturing the organic light-emitting display apparatuses have problems in that encapsulation layers on the organic light-emitting devices are not planar, which may cause defects due to the formation of pixel lines and may adversely affect service life of the organic light-emitting devices.

### SUMMARY

Aspects of embodiments of the present invention relate to an organic light-emitting display apparatus and a method of manufacturing the organic light-emitting display apparatus, and more particularly, to an organic light-emitting display apparatus having excellent sealability and a method of manufacturing the organic light-emitting display apparatus. Additional aspects will be set forth in part in the description that follows and in part will be apparent from the description, or may be learned by practice of the presented embodiments.

According to an embodiment of the present invention, an organic light-emitting display apparatus is provided. The organic light-emitting display apparatus includes: a substrate; an organic light-emitting device on the substrate; and an encapsulation layer including a first inorganic film covering the organic light-emitting device, an organic film on the first inorganic film, a second inorganic film between the first inorganic film and the organic film and having hydrophilicity, and a third inorganic film on the organic film.

The second inorganic film may have a contact angle of 40° or less.

The second inorganic film may include metallic oxide or nonmetallic oxide.

The second inorganic film may include the nonmetallic oxide, and the nonmetallic oxide may include silicon oxide.

The second inorganic film may include the metallic oxide, and the metallic oxide may include aluminum oxide.

The second inorganic film may have a thickness greater than or equal to 10 Å and less than or equal to 1 μm.

The second inorganic film may have a compressive strength of 300 MPa or less.

The second inorganic film may have surface energy of 40 mN/m or more.

The second inorganic film may be formed by using low temperature radio frequency-plasma enhanced chemical vapor deposition (RF-PECVD).

The organic film may be formed by using an ink-jet printing method.

According to another embodiment of the present invention, a method of manufacturing an organic light-emitting display apparatus is provided. The method includes forming an organic light-emitting device on a substrate, forming a first inorganic film covering the organic light-emitting device, forming a second inorganic film having hydrophilicity on the first inorganic film, forming an organic film on the second inorganic film, and forming a third inorganic film on the organic film.

The second inorganic film may have a contact angle of 40° or less.

The forming of the organic film may include forming the organic film by using an ink-jet printing method.

In the forming of the second inorganic film, the second inorganic film may include metallic oxide or nonmetallic oxide.

The second inorganic film may include the nonmetallic oxide, and the nonmetallic oxide may include silicon oxide.

The second inorganic film may include the metallic oxide, and the metallic oxide may include aluminum oxide.

In the forming of the second inorganic film, the second inorganic film may have a thickness greater than or equal to 10 Å and less than or equal to 1 μm.

In the forming of the second inorganic film, the second inorganic film may have a compressive strength of 300 MPa or less.

In the forming of the second inorganic film, the second inorganic film may have surface energy of 40 mN/m or more.

The forming of the second inorganic film may include forming the second inorganic film by using low temperature radio frequency-plasma enhanced chemical vapor deposition (RF-PECVD).

These general and specific embodiments may be implemented by using a system, a method, a computer program, or a combination thereof.

### BRIEF DESCRIPTION OF THE DRAWINGS

These and/or other aspects of the present invention will become more apparent and more readily appreciated from the following description of example embodiments, taken in conjunction with the accompanying drawings in which:

FIG. 1 is a schematic cross-sectional view of an organic light-emitting display apparatus according to an embodiment of the present invention;

FIG. 2 is a detailed cross-sectional view of section II of the organic light-emitting display apparatus of FIG. 1;

FIG. 3 is a schematic cross-sectional view of a layered structure of an encapsulation layer of the organic light-emitting display apparatus of FIG. 1;

FIG. 4 is a graph illustrating changes in contact angle and compressibility of a second inorganic film due to radio frequency (RF) power, according to embodiments of the present invention;

FIG. 5 is a graph illustrating changes in contact angle and compressibility of a second inorganic film due to pressure, according to embodiments of the present invention; and

FIG. 6 is a graph illustrating changes in contact angle and compressibility of a second inorganic film due to the amount of oxygen, according to embodiments of the present invention.

### DETAILED DESCRIPTION

As the present invention allows for various changes and numerous embodiments, example embodiments will be illustrated in the drawings and described in detail in the written description. Aspects and features of the present invention will become apparent from the following description of example embodiments in detail, taken in conjunction with the accompanying drawings. The present invention may, however, be embodied in many different forms and should not be construed as limited to the example embodiments set forth herein.

Reference will now be made in detail to example embodiments, which are illustrated in the accompanying drawings. Like reference numerals in the drawings denote like elements and thus, repeated descriptions thereof may be omitted. The term “and/or” used herein includes any and all combinations of one or more of the associated listed items.

While such terms as “first” and “second” may be used to describe various components, such components should not be limited to the above terms. The above terms are used primarily to distinguish one component from another. The singular forms “a,” “an,” and “the” used herein are intended to include the plural forms as well, unless the context clearly indicates otherwise.

It will be understood that the terms such as “include,” “comprise,” and “have” specify the presence of stated features or components, but do not preclude the presence or addition of one or more other features or components. It will be further understood that when a layer, region, or component is referred to as being “formed on” another layer, region, or component, it can be directly or indirectly formed on the other layer, region, or component. That is, for example, intervening layers, regions, or components may also be present.

Sizes of components in the drawings may be exaggerated for convenience of explanation. In other words, since sizes and thicknesses of components in the drawings may be arbitrarily illustrated for convenience of explanation, the present invention is not limited thereto.

In the following examples, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an embodiment may be implemented differently, a specific process order may be performed differently from the described order. For example, two consecutively described processes may be performed substantially at the same time or performed in an order opposite to the described order.

Herein, the use of the term “may,” when describing embodiments of the present invention, refers to “one or more embodiments of the present invention.” In addition, the use of alternative language, such as “or,” when describing embodiments of the present invention, refers to “one or more embodiments of the present invention” for each corresponding item listed.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

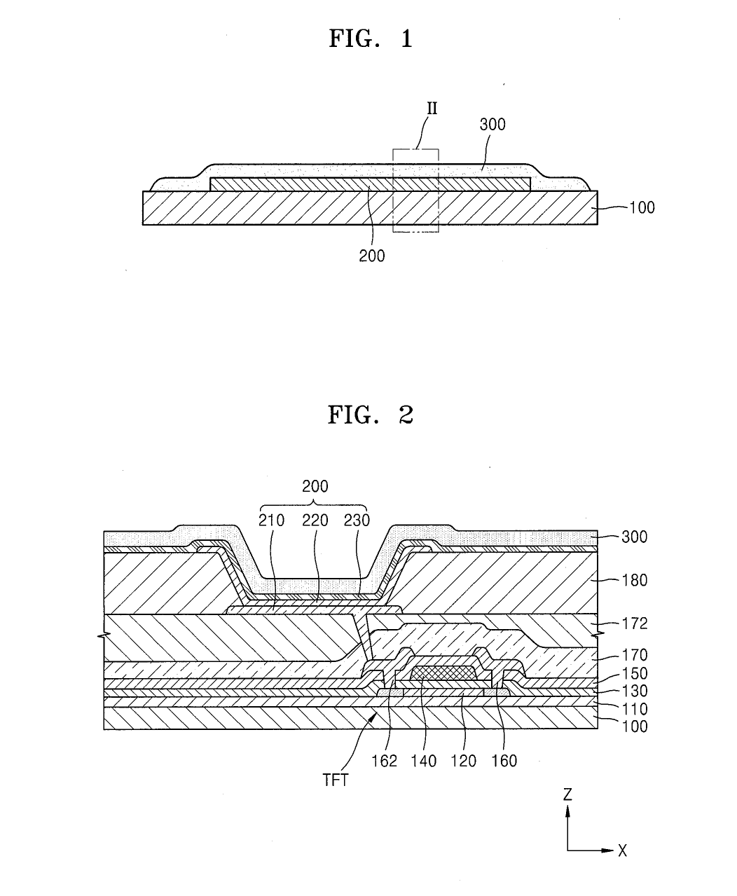

FIG. 1 is a schematic cross-sectional view of an organic light-emitting display apparatus according to an embodiment of the present invention, and FIG. 2 is a detailed cross-sectional view of section II of the organic light-emitting display apparatus of FIG. 1.

Referring to FIG. 1, the organic light-emitting display apparatus includes a substrate 100, an organic light-emitting device (or devices) 200 disposed on the substrate 100, and an encapsulation layer 300 disposed to cover the organic light-emitting devices 200. The substrate 100 may be a flexible substrate and may include plastic with excellent heat-resisting properties and durability. For example, the substrate 100 may include one selected from the group consisting of polyethersulfone (PES), polyacrylate (PA), polyetherimide (PEI), polyethylene naphthalate (PEN), polyethylene terephthalate (PET), polyphenylene sulfide (PPS), polyarylate (PAR), polyimide (PI), polycarbonate (PC), cellulose triacetate (TAC), cellulose acetate propionate (CAP), poly(arylene ether sulfone), and a combination thereof. However, embodiments of the present invention are not limited thereto, and in other embodiments, the substrate 100 may include various materials, such as metal or glass.

The organic light-emitting devices 200 may be disposed on the substrate 100. Each organic light-emitting device 200 may include a pixel electrode 210, an intermediate layer 220 including an emission layer, and an opposite electrode 230 disposed on the intermediate layer 220 to face the pixel electrode 210. For example, the organic light-emitting devices 200 may be disposed directly on the substrate 100 or various layers may be formed on the substrate 100 and the organic light-emitting devices 200 disposed on the various layers.

The encapsulation layer 300 may be disposed on the organic light-emitting devices 200 to cover the organic light-emitting devices 200. The encapsulation layer 300 may have a multi-layered structure to seal the organic light-emitting devices 200 to protect the organic light-emitting devices 200 from external moisture, oxygen, and the like.

Referring to FIG. 2, a buffer layer 110 may be disposed on top of the substrate 100. The buffer layer 110 may be formed on the substrate 100, for example, to prevent impurities from penetrating into thin film transistors (TFTs), capacitors, the organic light-emitting devices 200, and the like, which are formed on the substrate 100. The buffer layer 110 may include a single layer or multiple layers of one or more materials such as silicon oxide or silicon nitride.

The TFTs and capacitors may be disposed on the buffer layer 110, and the organic light-emitting devices 200 electrically connected to the TFTs and capacitors positioned on the buffer layer 110. Each TFT may include a semiconductor layer 120 including, for example, amorphous silicon, polycrystalline silicon, or an organic semiconductor material, a gate electrode 140, a source electrode 160, and a drain electrode 162. A general structure of the TFT will now be described in detail.

The buffer layer 110 including silicon oxide, silicon nitride, or the like may be disposed on the substrate 100, for example, to planarize a surface of the substrate 100 or to prevent impurities or the like from penetrating into the semiconductor layer 120 of the TFT, and the semiconductor layer 120 may be positioned on the buffer layer 110.

The gate electrode 140 may be disposed on the semiconductor layer 120, and according to a signal applied to the gate electrode 140, the source electrode 160 and the drain electrode 162 may be electrically connected to each other. The gate electrode 140 may include a single layer or multiple layers of, for example, one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) by taking into account adhesiveness to an adjacent layer, surface smoothness of a stacked layer, processability, and the like.

In this regard, in order to secure insulation between the semiconductor layer 120 and the gate electrode 140, a gate insulation layer 130, which includes, for example, silicon oxide and/or silicon nitride, may be disposed between the semiconductor layer 120 and the gate electrode 140. An interlayer dielectric layer 150 may be disposed on the gate electrode 140 and may include a single layer or multiple layers of one or more materials such as silicon oxide or silicon nitride.

The source electrode 160 and the drain electrode 162 may be disposed on the interlayer dielectric layer 150. The source electrode 160 and the drain electrode 162 may each be electrically connected to the semiconductor layer 120 through contact holes formed in the interlayer dielectric layer 150 and the gate insulation layer 130. The source electrode 160 and the drain electrode 162 may include a single layer or multiple layers of, for example, one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) by taking into account conductivity and the like.

A protection layer 170 may be disposed on the interlayer dielectric layer 150, covering the thin film transistor TFT to protect the thin film transistor TFT having the above-described structure. The protection layer 170 may include, for example, an inorganic material such as silicon oxide, silicon nitride, or silicon oxynitride.

A first insulation layer 172 may be disposed on the substrate 100. Here, the first insulation layer 172 may, for example, be a planarization layer or a protection layer. When the organic light-emitting devices 200 are disposed on the TFTs, the first insulation layer 172 substantially planarizes the top surface of the TFTs and protects the TFTs and various devices. The first insulation layer 172 may include, for example, an acryl-based organic material or benzocyclobutene (BCB). In this regard, the buffer layer 110, the gate insulation layer 130, the interlayer dielectric layer 150, and the first insulation layer 172 may be formed on the entire surface of the substrate 100.

A second insulation layer 180 may be disposed on the TFTs. Here, the second insulation layer 180 may be a pixel-defining layer. The second insulation layer 180 may be positioned on the above-described first insulation layer 172 and may have openings, for example, to define a pixel area (or areas) of the substrate 100.

The second insulation layer 180 may be provided as, for example, an organic insulation layer. The organic insulation layer may include an acryl-based polymer such as poly(methyl methacrylate) (PMMA), polystyrene (PS), a polymer derivative containing a phenol group, an imide-based polymer, an aryl ether-based polymer, an amide-based polymer, a fluorine-based polymer, a p-xylene-based polymer, a vinyl alcohol-based polymer, or a mixture thereof.

The organic light-emitting devices 200 may be disposed on the second insulation layer 180. Each organic light-emitting device 200 may include the pixel electrode 210, the intermediate layer 220 including an emission layer (EML), and the opposite electrode 230.

The pixel electrode 210 may be formed as a (semi) transparent electrode or a reflective electrode. When the pixel electrode 210 is formed as a (semi) transparent electrode, the pixel electrode 210 may include, for example, indium tin oxide (ITO), indium zinc oxide (IZO), zinc oxide (ZnO), indium oxide (In₂O₃), indium gallium oxide (IGO), or aluminum zinc oxide (AZO). When the pixel electrode 210 is formed as a reflective electrode, the pixel electrode 210 may include, for example, a reflective layer including Ag, Mg, Al, Pt, Pd, Au, Ni, Nd, Ir, Cr, or a compound thereof, and a layer including ITO, IZO, ZnO, In₂O₃, IGO, or AZO. However, the present invention is not limited thereto, and in other embodiments, the pixel electrode 210 may include various materials. In addition, a structure of the pixel electrode 210 may have various modifications, such as a single layer or multiple layers.

The intermediate layer 220 may be disposed in the pixel area defined by the second insulation layer 180. The intermediate layer 220 may include an EML that emits light according to an electrical signal. In addition to the EML, the intermediate layer 220 may include a hole injection layer (HIL) and a hole transport layer (HTL) disposed between the EML and the pixel electrode 210, an electron transport layer (ETL) and an electron injection layer (EIL) disposed between the EML and the opposite electrode 230, and the like stacked on one another in a single or complex structure. However, the intermediate layer 220 is not limited thereto and may have various structures.

The HTL, the HIL, the ETL, and the EIL may be formed as one body on the entire surface of the substrate 100, and only the EML may be formed for each pixel by using an ink-jet printing process. The HTL, the HIL, the ETL, the EIL, and the like may be positioned in an inlet portion as well.

The opposite electrode 230, which covers the intermediate layer 220 including the EML and faces the pixel electrode 210, may be disposed on the entire surface of the substrate 100. The opposite electrode 230 may be formed as a (semi) transparent electrode or a reflective electrode.

When the opposite electrode 230 is formed as a (semi) transparent electrode, the opposite electrode 230 may include, for example, a layer including metal having a small work function, that is, Li, Ca, LiF/Ca, LiF/Al, Al, Ag, Mg, or a compound thereof, and a (semi) transparent conductive layer including ITO, IZO, ZnO, In₂O₃, or the like. When the opposite electrode 230 is formed as a reflective electrode, the opposite electrode 230 may include, for example, a layer including Li, Ca, LiF/Ca, LiF/Al, Al, Ag, Mg, or a compound thereof. However, the structure and materials of the opposite electrode 230 are not limited thereto and may have various modifications.

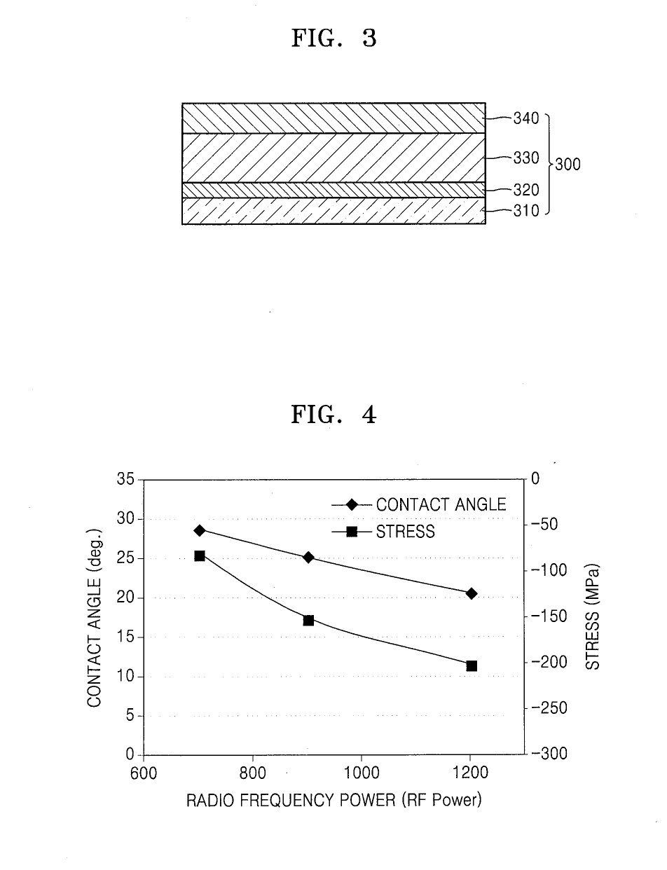

The encapsulation layer 300 may be disposed on the opposite electrode 230 to cover the opposite electrode 230. The encapsulation layer 300 may have a multi-layered structure including at least an inorganic film and an organic film that are stacked. A structure of the encapsulation layer 300 according to one embodiment of the present invention will be described in detail with reference to FIG. 3.

FIG. 3 is a schematic cross-sectional view of the structure of the encapsulation layer 300 of the organic light-emitting display apparatus of FIG. 1. Referring to FIG. 3, the encapsulation layer 300 may include a first inorganic film 310, a second inorganic film 320, an organic film 330, and a third inorganic film 340. The first inorganic film 310 may be disposed on the opposite electrode 230 to cover the opposite electrode 230 and seal the organic light-emitting devices 200. The first inorganic film 310 may include, for example, an inorganic material such as silicon nitride.

The organic film 330 may be disposed on the first inorganic film 310. The organic film 330 may include, for example, an organic material such as one or more materials selected from the group consisting of acryl-based resin, methacrylic resin, polyisoprene, vinyl-based resin, epoxy-based resin, urethane-based resin, cellulose-based resin, parylene-based resin, and imide-based resin.

The organic film 330 may be disposed on the first inorganic film 310, and the third inorganic film 340 may be disposed on the organic film 330. The third inorganic film 340 may include, for example, an inorganic material such as silicon nitride. The first inorganic film 310 and the third inorganic film 340 may include identical materials or may include different materials from each other.

The organic film 330 may be formed by using an ink-jet printing method. In forming comparable encapsulation layers, when at least two organic films are formed on an inorganic film by using a thermal deposition method, the organic films may fail to spread evenly at the perimeter of a panel, which may cause problems such as uniformity defects due to panel contraction and waste of organic film material due to forming multiple organic films. Accordingly, in some embodiments of the present invention, since the organic film 330 is formed by using the ink-jet printing method instead of alternatives such as the thermal deposition method, the waste of materials of the organic film 330 may be resolved by providing the organic film 330 as a single layer, and the rate of uniformity defects due to panel contraction may be improved.

However, when the organic film is formed by using the ink-jet printing method, the contact angle of the organic film may increase depending on the kind of organic material discharged from the ink-jet nozzles and the status of a lower film of the organic film, and the spreadability of the organic film may be uneven. Thus, defects along the lines of pixels may occur and weaken the sealing force of the encapsulation layer, which may adversely influence the service life of the organic light-emitting devices. Accordingly, in some embodiments of the present invention, the second inorganic film 320, which may be an inorganic film that has hydrophilicity, is formed under the organic film 330. That is, since the second inorganic film 320 has hydrophilicity, the contact angle of the organic film 330 as disposed on the second inorganic film 320 may decrease and spreadability of the organic film 330 may be even.

As described above, the second inorganic film 320 may be disposed between the first inorganic film 310 and the organic film 330, and the organic film 330 may be in direct contact with the second inorganic film 320. In this regard, the second inorganic film 320 may be formed by using low temperature radio frequency-plasma enhanced chemical vapor deposition (RF-PECVD).

In addition, the second inorganic film 320 may be formed to have a contact angle of 40° or less. That is, the contact angle between the second inorganic film 320 and the organic film 330 disposed on the second inorganic film 320 may be less than or equal to 40°. The contact angle is an angle formed when a liquid is in thermodynamic equilibrium on a solid surface and is a measure of the wettability of a solid surface. Having a small contact angle as described above implies displaying an excellent wettability and a high surface energy and having hydrophilicity. On the other hand, having a large contact angle implies displaying a poor wettability and a low surface energy and having hydrophobicity. When the second inorganic film 320 has a contact angle of 40° or less, a film disposed on the second inorganic film 320 may have a good spreadability.

Although there may be a variety of methods of measuring the contact angle, such as a sessile drop method using a droplet, direct measurement using a goniometer, a tilting method, a Neumann method, a capillary method, and a Wesburn method, embodiments are not limited thereto. In some embodiments of the present invention, the contact angle of the second inorganic film 320 may be measured by using the sessile drop method using a droplet.

In detail, the second inorganic film 320, which includes oxygen-rich metallic oxide or nonmetallic oxide, is formed on the substrate 100 to have a thickness greater than or equal to 10 Å and less than or equal to 1 μm, and then positioned on a contact angle measuring instrument at room temperature. After a droplet is dropped on the second inorganic film 320, the contact angle of the droplet on the second inorganic film 320 is measured by using a contact angle measuring program. Although the droplet may be formed of water (H₂O) or may include an organic material, in some embodiments of the present invention, the droplet formed of water is used to measure the contact angle. The contact angle measured may be less than or equal to 40°, as described above, on the second inorganic film 320.

When the droplet on the second inorganic film 320 has a contact angle less than or equal to 40°, the wettability of the second inorganic film 320 may be excellent and a surface of the second inorganic film 320 may be hydrophilic. Accordingly, the organic film 330 formed on the second inorganic film 320 may display even spreadability on the surface of the second inorganic film 320 that has hydrophilicity and thus, the encapsulation layer 300 having an excellent sealing force may be formed.

In a comparable organic light-emitting display apparatus, when forming the organic film 330 directly on the first inorganic film 310 (which includes, for example, silicon nitride) without the second inorganic film 320 therebetween, the contact angle of the organic film 330 on the first inorganic film 310 was measured to exceed 40°. As described above, this may cause spreadability of the organic film 330 to be uneven, which may cause defects in the encapsulation layer. Accordingly, in some embodiments of the present invention, the second inorganic film 320 having hydrophilicity may be further formed on the first inorganic film 310 to decrease the contact angle of the organic film 330 on the second inorganic film 320 to 40° or less, improve the spreadability of the organic film 330, and furthermore, enhance a sealing force of the encapsulation layer 300.

The second inorganic film 320 may include, for example, oxygen-rich metallic oxide or nonmetallic oxide. Examples of the metallic oxide include aluminum oxide (AlOx), and examples of the nonmetallic oxide include silicon oxide (SiOx). As the percentage of oxygen in the second inorganic film 320 increases, the number of O—H bonds on a surface of the second inorganic film 320 may increase and thus, the contact angle may decrease, which helps increase the spreadability of the organic film 330.

The second inorganic film 320 may have a thickness greater than or equal to 10 Å and less than or equal to 1 μm and may have a compressive strength of 300 MPa or less. If the thickness of the second inorganic film 320 is greater than 1 μm or the compressive strength of the second inorganic film 320 is greater than 300 MPa, peeling may occur with respect to the second inorganic film 320 and/or the organic film 330.

In addition, surface energy of the second inorganic film 320 may be greater than or equal to 40 mN/m. Surface energy is a force that the surface of a material has, the force attracting an external material due to the force of attraction of molecules of the outermost layer. Having high surface energy means that intermolecular attractive forces are great at the interface of a material, and as surface energy increases, surface tension at the interface of a material increases. Accordingly, as surface energy of the second inorganic film 320 increases, the contact angle of the organic film 330 (which is formed on the second inorganic film 320) on a surface of the second inorganic film 320 decreases, and the wettability of the surface of the second inorganic film 320 improves.

In a comparable organic light-emitting display apparatus, when forming the organic film 330 directly on the first inorganic film 310 (which includes, for example, silicon nitride) without the second inorganic film 320 therebetween, surface energy of the first inorganic film 310 was measured to be less than 40 mN/m. As described above, this may cause spreadability of the organic film 330 to be uneven, which may cause defects in the encapsulation layer. Accordingly, in some embodiments of the present invention, the second inorganic film 320 having hydrophilicity may be further formed on the first inorganic film 310. The second inorganic film 320 on which the organic film 330 is formed may be formed to have surface energy of 40 mN/m or greater to improve the spreadability of the organic film 330 and furthermore, enhance a sealing force of the encapsulation layer 300.

Although embodiments of an organic light-emitting display apparatus have been mainly described, the present invention is not limited thereto. For example, methods of manufacturing the organic light-emitting display apparatus are also included in the scope of the present invention.

An organic light-emitting device may be formed on a substrate with reference to FIGS. 1 to 3. In this regard, the description that the organic light-emitting device is formed on the substrate includes not only when the organic light-emitting device is formed directly on the substrate but also when various layers are formed on the substrate and the organic light-emitting device is formed thereon. For example, as illustrated in FIG. 2, a thin film transistor may be formed on the substrate and a first insulation layer or a protection layer may cover the thin film transistor. Thus, the organic light-emitting device may be disposed on the first insulation layer.

Elements of the organic light-emitting display apparatus are formed on a substrate 100. The substrate 100 may include a transparent material, for example, glass, plastic, or metal.

Common layers such as a buffer layer 110, a gate insulation layer 130, an interlayer dielectric layer 150, and a protection layer 170 may be formed on the entire surface of the substrate 100. On the buffer layer 110, a patterned semiconductor layer 120 including a channel region, a source contact region, and a drain contact region may be formed, and a gate electrode 140, a source electrode 160, and a drain electrode 162, which are elements of a thin film transistor, along with the patterned semiconductor layer, may be formed.

In addition, a first insulation layer 172 covering the thin film transistor and substantially planarizing the top surface of the thin film transistor may be formed on the entire surface of the substrate 100. A via hole may be formed in the first insulation layer 172, and a pixel electrode 210 may be electrically connected to the thin film transistor through the via hole.

The pixel electrode 210 may be patterned according to each pixel and thus formed on the first insulation layer 172. A second insulation layer 180 covering edges of the pixel electrode 210 and having an opening that defines each pixel region may be formed on the first insulation layer 172 to substantially correspond to the entire surface of the substrate 100.

On the pixel electrode 210 that is exposed by the second insulation layer 180, an intermediate layer 220 having a multi-layered structure and including an emission layer may be formed, and then an opposite electrode 230 substantially corresponding to the entire surface of the substrate 100 may be formed. Unlike as illustrated in FIG. 2, in some embodiments, a portion of the intermediate layer 220 may be a common layer substantially corresponding to the entire surface of the substrate 100, and another portion of the intermediate layer 220 may be a pattern layer patterned to correspond to the pixel electrode 210.

An encapsulation layer 300 may be formed on the organic light-emitting device. A first inorganic film 310 covering the organic light-emitting device may be formed as a first step to forming the encapsulation layer 300. For example, the first inorganic film 310 may include silicon nitride.

Next, a second inorganic film 320 may be formed on the first inorganic film 310. For example, the second inorganic film 320 may be formed by using low temperature RF-PECVD.

The second inorganic film 320 may be formed to have a contact angle of 40° or less. That is, the contact angle between the second inorganic film 320 and an organic film 330 disposed on the second inorganic film 320 may be less than or equal to 40°. When the second inorganic film 320 has a contact angle of 40° or less, the second inorganic film 320 may have a good spreadability. This is related to forming the organic film 330 on the second inorganic film 320 by using an ink-jet printing method, which will be described later.

The second inorganic film 320 may include, for example, oxygen-rich metallic oxide or nonmetallic oxide. For example, aluminum oxide (AlOx) may be used as the metallic oxide, and silicon oxide (SiOx) may be used as the nonmetallic oxide. As the second inorganic film 320 is formed by using oxygen-rich metallic oxide or nonmetallic oxide, and the percentage of oxygen in the second inorganic film 320 increases, the number of O—H bonds on a surface of the second inorganic film 320 may increase and thus, the contact angle may decrease, which may increase the spreadability of the organic film 330.

In order to form the second inorganic film 320 where spreadability of an organic material is excellent, a variety of variables may be considered.

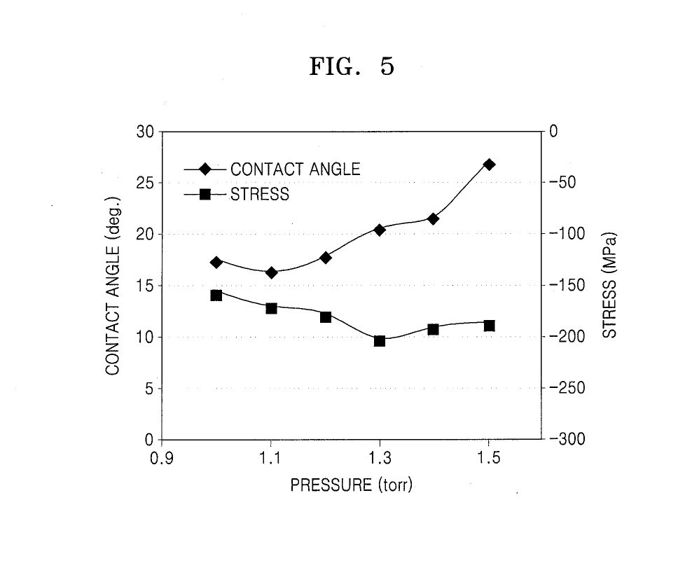

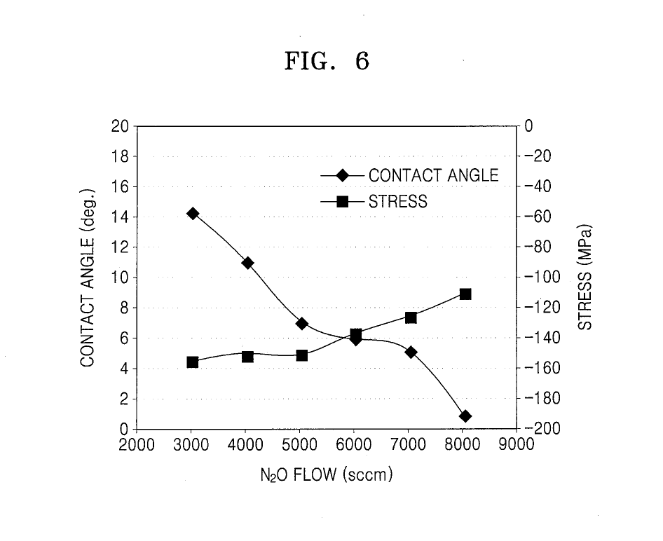

FIG. 4 is a graph illustrating changes in contact angle and compressibility of the second inorganic film 320 due to RF power, according to embodiments of the present invention. FIG. 5 is a graph illustrating changes in contact angle and compressibility of the second inorganic film 320 due to pressure, according to embodiments of the present invention. FIG. 6 is a graph illustrating changes in contact angle and compressibility of the second inorganic film 320 due to the amount of oxygen, according to embodiments of the present invention.

Referring to FIG. 4, as RF power increases, the contact angle decreases, and compressibility has a tendency of increasing. Here, as RF power increases, collision between atoms increases and thus, ionization efficiency increases. In this regard, as collision between atoms increases, ionization efficiency of oxygen supplying gas increases and thus, the amount of oxygen in the second inorganic film 320 increases. Accordingly, as the number of O—H bonds on a surface of the second inorganic film 320 increases due to the increased amount of oxygen, oxygen increases and hydrogen decreases in the second inorganic film 320. Thus, spreadability improves, and the contact angle decreases. FIG. 4 shows a result that the contact angle decreases from about 28.7° to about 20.7° according to the change in starting and final RF power conditions.

Referring to FIG. 5, as pressure increases, the contact angle increases, and compressibility also has a tendency of substantially increasing although the increase is not drastic. That is, as pressure increases, the number of active oxygen decreases and thus, the contact angle tends to increase.

Referring to FIG. 6, the contact angle and compressibility change remarkably according to the flow of oxygen supplying gas. In this regard, N₂O or the like may be used as the oxygen supplying gas. That is, as the flow of oxygen supplying gas increases, the contact angle decreases from 14° to 1°, and the compressibility also decreases from 158 MPa to 110 MPa. The reason is that as the flow of oxygen supplying gas increases, the number of O—H bonds increases.

In some embodiments, the second inorganic film 320 may be formed, and then plasma treatment may be performed thereon. Thus, the number of O—H bonds on a surface of the second inorganic film 320 may increase.

The change in characteristics of the second inorganic film 320 according to various deposition conditions was measured as described above, and the second inorganic film 320 was deposited by selecting conditions under which the contact angle of the second inorganic film 320 achieved its smallest measured value. On the second inorganic film 320 formed under such an optimized set of conditions, the organic film 330 was coated by using an ink-jet printing method, and then characteristics of the organic film 330 were observed. As a result, the organic film 330 on the second inorganic film 320 had complete filling. In addition, after the whole encapsulation layer 300 was formed, even under a harsh condition (85°, 85%, 500 hr, such as a specific condition including a temperature of 85° Celsius, 85 percent moisture environment, and exposure for 500 hours in a thermo-hygrostat) for reliability evaluation, problems such as lighting defects did not occur.

The second inorganic film 320 may be formed to have a thickness greater than or equal to 10 Å and less than or equal to 1 μm and may have a compressive strength of 300 MPa or less. If a thickness of the second inorganic film 320 is greater than 1 μm or a compressive strength of the second inorganic film 320 is greater than 300 MPa, peeling may occur with respect to the second inorganic film 320 and/or the organic film 330.

In addition, surface energy of the second inorganic film 320 may be greater than or equal to 40 mN/m. Surface energy refers to a force that the surface of a material has, the force attracting an external material due to the force of attraction of molecules of the outermost layer. Having a high surface energy means that intermolecular attractive forces are great at the interface of a material, and as surface energy is higher, surface tension at the interface of a material is higher. Accordingly, as surface energy of the second inorganic film 320 is higher, the contact angle of the organic film 330 (which is formed on the second inorganic film 320) on a surface of the second inorganic film 320 is smaller, and the wettability of the surface of the second inorganic film 320 improves.

In a comparable organic light-emitting display apparatus, when forming the organic film 330 directly on the first inorganic film 310 (which includes, for example, silicon nitride) without the second inorganic film 320 therebetween, surface energy of the first inorganic film 310 was measured to be less than 40 mN/m. As described above, this may lead to the spreadability of the organic film 330 to be uneven, which may cause defects in the encapsulation layer. Accordingly, in some embodiments of the present invention, the second inorganic film 320 having hydrophilicity may be further formed on the first inorganic film 310. The second inorganic film 320, on which the organic film 330 is formed, may be formed to have surface energy of 40 mN/m or greater to improve the spreadability of the organic film 330 and furthermore, enhance a sealing force of the encapsulation layer 300.

Thereafter, the organic film 330 may be formed on the first inorganic film 310, and a third inorganic film 340 may be formed on the organic film 330. For example, as with the first inorganic film 310, the third inorganic film 340 may include silicon nitride. The organic film 330 may include, for example, one or more materials selected from the group consisting of acryl-based resin, methacrylic resin, polyisoprene, vinyl-based resin, epoxy-based resin, urethane-based resin, cellulose-based resin, and parylene-based resin.

The organic film 330 according to some embodiments of the present invention may be formed by using an ink-jet printing method. In forming an encapsulation layer in comparable organic light-emission display apparatuses, when at least two organic films are formed on an inorganic film by using a thermal deposition method, the organic films may fail to spread evenly at the perimeter of a panel, which may cause problems such as uniformity defects due to panel contraction and waste of organic film material due to forming multiple organic films.

Accordingly, in some embodiments of the present invention, since the organic film 330 is formed by using the ink-jet printing method as an alternative to the thermal deposition method, the waste of material of the organic film 330 may be resolved by providing the organic film 330 as a single layer, and the uniformity defect rate due to panel contraction may be improved.

When the organic film 330 is formed by using the ink-jet printing method, the contact angle, spreadability, and the like of the organic film vary depending on the kind of an organic material discharged from the ink-jet nozzles and the status of a lower film of the organic film. Thus, defects due to pixel lines occur and weaken a sealing force of the encapsulation layer 300, which may have an adverse influence on the service life of the organic light-emitting devices. Accordingly, in some embodiments of the present invention, the second inorganic film 320, which has hydrophilicity, may be formed under the organic film 330 so that the contact angle of the organic film 330 may decrease and spreadability of the organic film 330 may be even.

According to one or more embodiments of the present invention, there is provided an organic light-emitting display apparatus having excellent sealability and a method of manufacturing the organic light-emitting display apparatus. It should be understood that the example embodiments described herein should be considered in a descriptive sense only and not for purposes of limitation. Descriptions of features or aspects within each embodiment should typically be considered as available for other similar features or aspects in other embodiments of the present invention.

While one or more embodiments of the present invention have been described with reference to the figures, it will be understood by those of ordinary skill in the art that various changes in form and details may be made therein without departing from the spirit and scope of the present invention as defined by the following claims and their equivalents.

What is claimed is:

1. An organic light-emitting display apparatus comprising:
a substrate;
an organic light-emitting device on the substrate; and
an encapsulation layer comprising a first inorganic film covering the organic light-emitting device, an organic film on the first inorganic film, a second inorganic film between the first inorganic film and the organic film and having hydrophilicity, and a third inorganic film on the organic film.

2. The apparatus of claim 1, wherein the second inorganic film has a contact angle of 40° or less.

3. The apparatus of claim 1, wherein the second inorganic film comprises metallic oxide or nonmetallic oxide.

4. The apparatus of claim 3, wherein the second inorganic film comprises the nonmetallic oxide,, and the nonmetallic oxide comprises silicon oxide.

5. The apparatus of claim 3, wherein the second inorganic film comprises the metallic oxide, and the metallic oxide comprises aluminum oxide.

6. The apparatus of claim 1, wherein the second inorganic film has a thickness greater than or equal to 10 Å and less than or equal to 1 μm.

7. The apparatus of claim 1, wherein the second inorganic film has a compressive strength of 300 MPa or less.

8. The apparatus of claim 1, wherein the second inorganic film has surface energy of 40 mN/m or more.

9. The apparatus of claim 1, wherein the second inorganic film is formed by using low temperature radio frequency-plasma enhanced chemical vapor deposition (RF-PECVD).

10. The apparatus of claim 1, wherein the organic film is formed by using an ink-jet printing method.

11. A method of manufacturing an organic light-emitting display apparatus, the method comprising:
forming an organic light-emitting device on a substrate;
forming a first inorganic film covering the organic light-emitting device;
forming a second inorganic film having hydrophilicity on the first inorganic film;
forming an organic film on the second inorganic film; and
forming a third inorganic film on the organic film.

12. The method of claim 11, wherein the second inorganic film has a contact angle of 40° or less.

13. The method of claim 11, wherein the forming of the organic film comprises forming the organic film by using an ink-jet printing method.

14. The method of claim 11, wherein, in the forming of the second inorganic film, the second inorganic film comprises metallic oxide or nonmetallic oxide.

15. The method of claim 14, wherein the second inorganic film comprises the nonmetallic oxide, and the nonmetallic oxide comprises silicon oxide.

16. The method of claim 14, wherein the second inorganic film comprises the metallic oxide, and the metallic oxide comprises aluminum oxide.

17. The method of claim 11, wherein, in the forming of the second inorganic film, the second inorganic film has a thickness greater than or equal to 10 Å and less than or equal to 1 μm.

18. The method of claim 11, wherein, in the forming of the second inorganic film, the second inorganic film has a compressive strength of 300 MPa or less.

19. The method of claim 11, wherein, in the forming of the second inorganic film, the second inorganic film has surface energy of 40 mN/m or more.

20. The method of claim 11, wherein the forming of the second inorganic film comprises forming the second inorganic film by using low temperature radio frequency-plasma enhanced chemical vapor deposition (RF-PECVD).
